(19) United States
(12) Patent Application Publication
(10) Pub. No.: US 2024/0296262 A1
(43) Pub. Date: Sep. 5, 2024

(54) INFORMATION PROCESSING DEVICE, INFORMATION PROCESSING METHOD, AND NON-TRANSITORY COMPUTER-READABLE MEDIUM STORING INFORMATION PROCESSING PROGRAM

(71) Applicant: TOYOTA JIDOSHA KABUSHIKI KAISHA, Toyota-shi (JP)

(72) Inventor: Kazuyuki SASAKI, Nisshin-shi (JP)

(21) Appl. No.: 18/413,478

(22) Filed: Jan. 16, 2024

(30) Foreign Application Priority Data
Mar. 2, 2023 (JP) 2023-032230

(51) Int. Cl. G06F 30/27

(52) U.S. Cl. CPC G06F 30/27

(57) ABSTRACT

An information processing method including, by a computer: receiving vehicle data, which is data relating to a vehicle and is accumulated for each predetermined period of time and for each unit relating to a predetermined operation, a number of units in the data relating to the predetermined operation being different for each predetermined period of time in accordance with use by a user: generating, by using principal components obtained by principal component analysis of the vehicle data, training data by reducing the number of units relating to the predetermined operation in the vehicle data, and aligning a number of dimensions of the vehicle data; and training a model of a neural network by using the training data.

### CROSS-REFERENCE TO RELATED APPLICATION

This application claims priority under 35 USC 119 from Japanese Patent Application No. 2023-032230, filed on Mar. 2, 2023, the disclosure of which is incorporated by reference herein.

### BACKGROUND

### Technical Field

The present disclosure relates to an information processing device, an information processing method, and a non-transitory computer-readable medium storing an information processing program.

### Related Art

Japanese Patent Application Laid-Open (JP-A) No. 2020-148560 discloses technology to improve prediction accuracy in a case of predicting the remaining life of a vehicle battery. In this technology, a prediction model for predicting the remaining life of a vehicle battery is trained based on training data including time series data of a deterioration index, and a remaining life, at a previous predetermined point in time of a vehicle battery for training, the life of the battery having expired. In addition, estimate values of the deterioration index are inserted for unmeasured portions of the deterioration index.

In the related art, an unmeasured portion is taken into consideration. It should be noted that in training of a model of a neural network, it is necessary to perform training while aligning the number of dimensions of data used in training. However, the number of dimensions of data is not taken into consideration in the related art.

Vehicle data collected from a vehicle for the number of dimensions is collected, for example, in trip units. A trip is a unit of movement of the vehicle, and is a unit that is counted in a case in which one trip is set from the start of movement to the end of movement, and the number of trips corresponds to dimensions of the data. Data relating to a vehicle may differ in the number of trips per day, resulting in a different number of dimensions of the data. For this reason, in training of a model, it is necessary to align the number of dimensions of data with different numbers of dimensions.

### SUMMARY

The present disclosure provides an information processing device, an information processing method, and a non-transitory computer-readable medium storing an information processing program, which enable a model of a neural network, with the number of dimensions of the data aligned, to be trained even in a case in which the number of dimensions of the data is different.

A first aspect of the present disclosure is an information processing method including, by a computer: receiving vehicle data, which is data relating to a vehicle and is accumulated for each predetermined period of time and for each unit relating to a predetermined operation, a number of units in the data relating to the predetermined operation being different for each predetermined period of time in accordance with use by a user: generating, by using principal components obtained by principal component analysis of the vehicle data, training data by reducing the number of units relating to the predetermined operation in the vehicle data, and aligning a number of dimensions of the vehicle data; and training a model of a neural network by using the training data.

The information processing method according to the first aspect of the present disclosure generates training data using principal component analysis. This enables training data including more data properties to be generated without missing data such as data using a representative value. Moreover, using a principal component as an element enables the model to be trained in which a number of dimensions is aligned to correspond to the input of the neural network.

A second aspect of the present disclosure, in the first aspect, may further include: grouping the vehicle data on a day-by-day basis as the predetermined period of time, and setting a maximum number of the units relating to the predetermined operation and a number of calculation target days, among the vehicle data that has been grouped; creating, for each item of the vehicle data, a first matrix according to the maximum number and the number of calculation target days; creating a second matrix according to the principal component obtained by the principal component analysis; and generating the training data by calculation of the first matrix and the second matrix.

The information processing method according to the second aspect of the present disclosure is capable of generating training data so as to reduce the number of operation data corresponding to a trip. The calculation of the first matrix and the second matrix reduces the maximum number of dimensions and generates training data aligned with the number of dimensions of the principal components of the second matrix.

In a third aspect of the present disclosure, in the second aspect, an average value or zero may be substituted into a blank portion of the first matrix to fill in a value.

The information processing method of the third aspect of the present disclosure enables data to be generated that can be calculated even in a case in which the number of trips is small or a case in which data acquisition is missing.

A fourth aspect of the present disclosure, in the first aspect, may further include: shaping a dimension of the vehicle data into a number of dimensions of the training data that was used in training of the trained model, by using a trained model that was training using the training data; and outputting an estimation result of the trained model.

The information processing method of the fourth aspect of the present disclosure is capable of dealing with input to the trained model by simple shaping of the vehicle data.

A fifth aspect of the present disclosure is an information processing device, including: a memory; and a processor coupled to the memory, the processor being configured to: receive vehicle data, which is data relating to a vehicle and is accumulated for each predetermined period of time and for each unit relating to a predetermined operation, a number of units in the data relating to the predetermined operation being different for each predetermined period of time in accordance with use by a user: generate, by using principal components obtained by principal component analysis of the vehicle data, training data by reducing the number of units relating to the predetermined operation in the vehicle data, and aligning a number of dimensions of the vehicle data; and train a model of a neural network by using the training data.

According to the above-described aspects, the information processing device, the information processing method, and the computer-readable medium non-transitory storing an information processing program of the present disclosure are capable of training a model of a neural network with the number of dimensions of the data aligned.

### BRIEF DESCRIPTION OF THE DRAWINGS

Exemplary embodiments will be described in detail based on the following figures, wherein:

FIG. 1 is a diagram illustrating a configuration of an information processing system including an information processing device;

FIG. 2 is a block diagram illustrating a hardware configuration of an information processing device;

FIG. 3 is a diagram schematically illustrating vehicle data for each trip which is acquired by grouping on a day-by-day basis;

FIG. 4A is a diagram schematically illustrating calculation target data that is generated from vehicle data in a range;

FIG. 4B is a diagram schematically illustrating training data generated by aligning the number of dimensions of vehicle data for each day;

FIG. 5 is a flowchart illustrating a flow of information processing during model training as an information processing method executed by the information processing device of the present exemplary embodiment; and

FIG. 6 is a flowchart illustrating a flow of information processing during estimation as an information processing method executed by the information processing device of the present exemplary embodiment.

### DETAILED DESCRIPTION

Explanation follows of an overview of exemplary embodiments of the present disclosure. In battery degradation estimation in a vehicle, in a case in which there are plural trips in one day, for example, calculation is performed by selecting a representative value such as a minimum value of a voltage at a start time of the day. Data that is input to a neural network for calculation is limited. For example, in a neural network, since product-sum operation is performed and then input to an activation function, the product-sum operation cannot be performed using coefficients of trained numerical values unless the number of dimensions are aligned. Further, null values cannot be calculated. If data can be acquired at regular intervals throughout one day, the number of dimensions can be aligned, and training and analysis can be performed. However, at the most regular intervals, data is acquired even in an ignition-off state in which the engine is not being driven, and this is not efficient in terms of energy efficiency.

For this reason, it is assumed that data acquisition is performed in trip units. However, the number of trips per day is not constant and cannot be specified because it depends on the use situation of the vehicle by the user. Therefore, in a case in which the model of the neural network has been trained according to the maximum number of trips, a weighting map changes according to the period of time, and there is a problem in that the trained coefficients cannot be used as they are. Further, it is preferable to utilize the information for each trip without limiting to a representative value for a single trip, such as a maximum value or a minimum value for each day. In addition, the number of dimensions needs to be reduced so as not to overly increase the calculation load.

Accordingly, in the present exemplary embodiment, a technique that enables data to be shaped using a principal component analysis technique to align the number of dimensions, and to be used in training of a model of a neural network, while using information from each trip, is proposed.

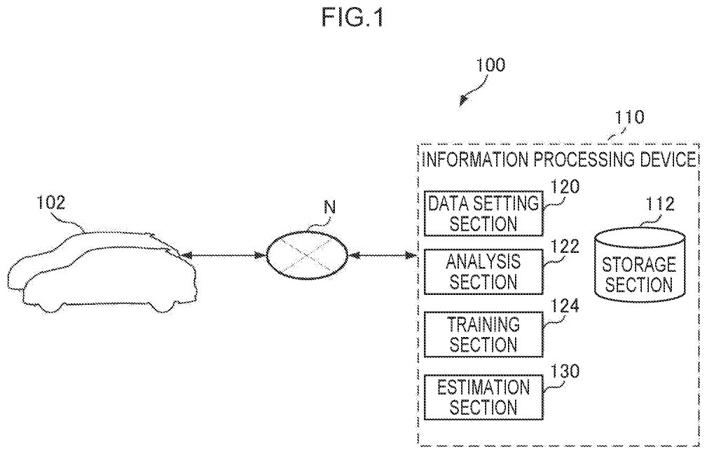

FIG. 1 is a diagram that illustrates a configuration of an information processing system 100. As illustrated in FIG. 1, the information processing system 100 includes plural vehicles 102 and an information processing device 110 which are connected together via a network N.

Each vehicle 102 transmits vehicle data relating to the vehicle 102 to the information processing device 110. Each vehicle 102 acquires numerical values of respective items of vehicle data based on the point in time at which the ignition is turned on, for each trip. The items of the vehicle data that is acquired are data such as a voltage (as an example, a voltage at a start time), a temperature (as an example, an outside air temperature), a travel distance (as an example, an accumulated travel distance), and a parking time period. It should be noted that the items that are acquired for each trip are variable according to the acquisition situation of the various sensors, and some items are not acquired. Accordingly, in the processing performed by an analysis section 122 that is described below, processing to fill in values of items that have not been acquired, is performed. A trip is an example of a unit relating to a predetermined operation.

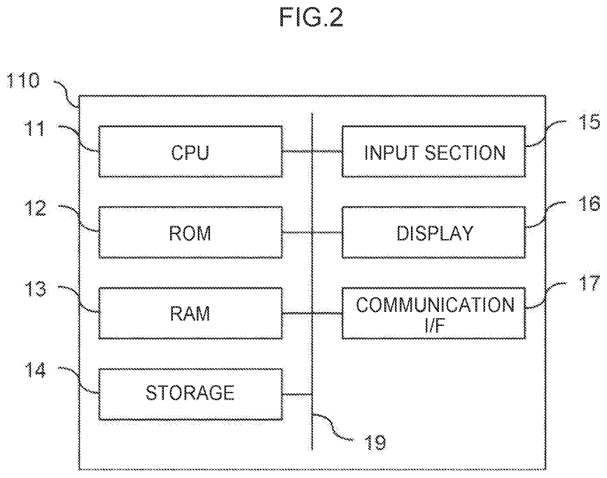

FIG. 2 is a block diagram that illustrates a hardware configuration of the information processing device 110. As illustrated in FIG. 2, the information processing device 110 includes a central processing unit (CPU) 11, read only memory (ROM) 12, random access memory (RAM) 13, storage 14, an input section 15, a display 16, and a communication interface (I/F) 17. These respective configurations are communicably connected to each other via a bus 19.

The CPU 11 is a central processing unit that executes various programs and controls various components. Namely, the CPU 11 reads a program from the ROM 12 or the storage 14, and executes the program using the RAM 13 as a workspace. The CPU 11 controls the respective configurations described above and performs a variety of computation processing in accordance with programs stored in the ROM 12 or the storage 14. In the present exemplary embodiment, an information processing program is stored in the ROM 12 or the storage 14. It should be noted that explanation of the other configurations is omitted since they may be as in the hardware configuration of a general computer.

At a time at which the above-described computer program is executed, the information processing device 110 implements various functions using the hardware resources described above. Explanation follows regarding functional configurations implemented by the information processing device 110.

As illustrated in FIG. 1, the functional configuration of the information processing device 110 includes a storage section 112, a data setting section 120, the analysis section 122, a training section 124, and an estimation section 130. The respective functional configurations are implemented by the CPU 11 reading and executing a computer program stored in the ROM 12 or the storage 14.

Vehicle data acquired from each vehicle 102 is accumulated at the storage section 112. The vehicle data is stored with an acquisition date and time allocated to each vehicle ID. A vehicle identification number (VIN) is used as a vehicle ID. The acquisition date and time corresponds to the time at which the ignition is turned ON. The vehicle data is stored with the acquisition date and time as a row and the respective items as columns. The vehicle data is accumulated with the number of trips differing from day to day in accordance with the use of the vehicle 102 by the user. This is because the number of trips differs according to the use of the vehicle 102 on that day by the user. Moreover, the storage section 112 stores the trained model that was trained.

The data setting section 120 receives vehicle data as an input, and sets calculation target data from the vehicle data. The number of days for which vehicle data is to be acquired may be determined based on an input from a user or a preset range, and the vehicle data may be grouped on a day-by-day basis so as to acquire a predetermined period of time based on the calculation point in time. Moreover, a maximum number of trips “a” and a number of calculation target days “b” are set in the calculation target data. As the maximum number of trips “a”, for example, the maximum number of trips in the acquired period of time is used. Further, for example, a predetermined number of previous days from the day on which calculation is executed is treated as the number of calculation target days “b”. Furthermore, the calculation target data is summarized for each day and for each trip. One day is an example of a predetermined period of time in the present disclosure. The maximum number of trips is an example of a maximum number in the present disclosure.

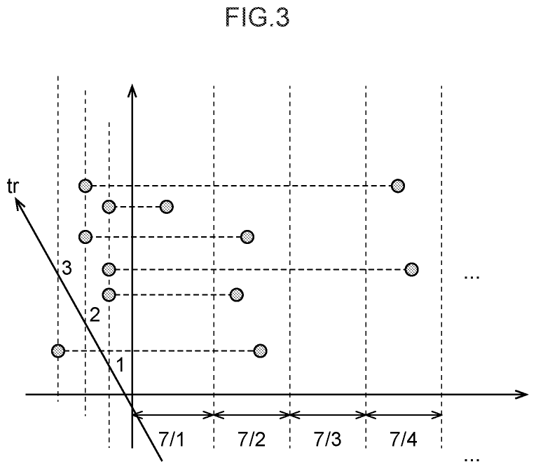

FIG. 3 is a diagram that schematically illustrates vehicle data for each trip which is acquired by grouping on a day-by-day basis. Each circle represents vehicle data acquired for one trip. Numerical values of the respective items are acquired as vehicle data using the respective circles. The horizontal axis represents time, and the vertical axis represents the value of an item. Since there are plural items, trips focused on a certain item are schematically illustrated. In the example of FIG. 3, trips acquired on each day from 7/1 to 7/4 are illustrated. 7/1 has one trip, 7/2 has three trips, 7/3 has zero trips, and 7/4 has two trip. In the group within this range, the maximum number of trips is represented by the direction of the arrow tr, and the maximum number of trips “a” is 3. As described above, the maximum number of trips of the selected range changes according to the vehicle data of the selected range.

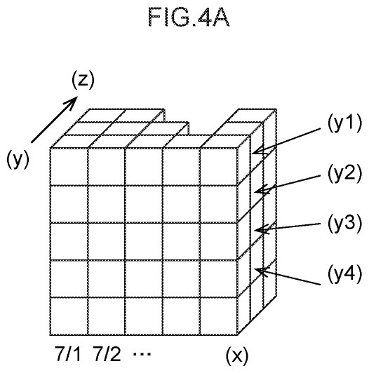

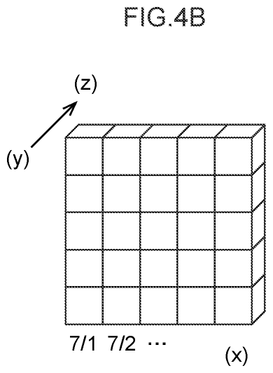

FIG. 4A is a diagram that schematically illustrates calculation target data that is generated from vehicle data in a range. The values of the respective items are entered at certain points in the respective blocks. The x-axis represents date units, the y-axis represents item units, and the z-axis represents trip units. For example, for each row in the y direction, the values of the respective items of voltage (y1), travel distance (y2), temperature (y3), and parking time period (y4) are stored. Since the number of trips differs from day to day, the number of blocks extending in the direction of the number of trips in the z-axis differs. Therefore, a portion having no value in an item is a blank portion (missing value: NA). It should be noted that the number of blocks is a schematic example, and is different from the example of FIG. 3.

The analysis section 122 obtains principal components from the analysis data by principal component analysis. The analysis section 122 uses the principal components obtained by the principal component analysis to align the number of dimensions of the vehicle data for each day, and generates training data. Details of processing are described in the flowcharts.

FIG. 4B is a diagram that schematically illustrates training data generated by aligning the number of dimensions of the vehicle data for each day. The example of FIG. 4B is an example in which blocks for each trip in the z-axis direction as illustrated in FIG. 4A are summarized and reduced to one dimension. Trips on each day are normalized, and the average is set to zero according to the value of each item. Principal components (PC) are projected in one axial direction by principal component analysis, thereby reducing data for the number of trips to one-dimensional data. It should be noted that whether or not reduction can actually be performed efficiently depends on the contribution rate of the principal component analysis. The contribution rate indicates to what extent the principal components explains the data in its entirety. The number of dimensions of the vehicle data aligned in the present exemplary embodiment is n (n≥1), and n-dimension training data is generated. For example, the n-dimension may be set so as to increase the number of dimensions until the contribution rate reaches 90%, or an arbitrary number of n that is less than the original number of trips may be set. Further, regarding portions for which the value of the item cannot be acquired and is missing, an average value or zero is substituted such that the dispersion of values is zero.

The training section 124 uses the generated training data to learn a model of a neural network. The model is a model for estimating the remaining life of a battery from the vehicle data. The training section 124 stores the trained model that was trained, in the storage section 112. It should be noted that training may be employed as a model for abnormality determination.

The estimation section 130 estimates the remaining life of the battery of the vehicle from the vehicle data using the trained model that was trained by the training section 124. Note that the vehicle data is pre-processed to align with the dimensions of the training data used in the training of the trained model, and then input to the trained model. The estimation section 130 inputs the pre-processed vehicle data to the trained model, and obtains an output of an estimation result of the remaining life of the battery from the trained model.

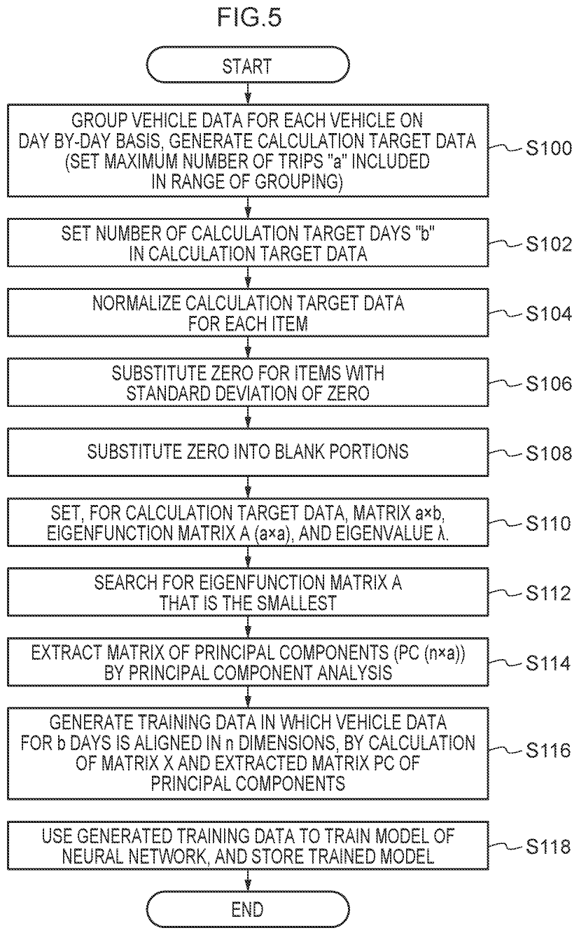

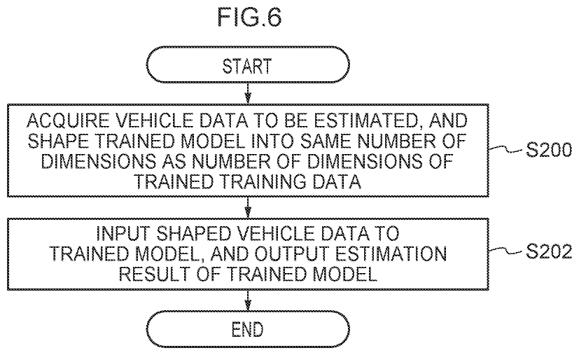

FIG. 5 and FIG. 6 are flowcharts that illustrate a flow of information processing as an information processing method executed by the information processing device 110 of the present exemplary embodiment. FIG. 5 illustrates information processing during model training, and FIG. 6 illustrates information processing during estimation. The information processing device 110 receives vehicle data from the vehicle 102 for each trip, and the vehicle data is accumulated at the storage section 112. The information processing device 110 performs information processing during model training for each predetermined period of time. The information processing device 110 performs information processing during estimation at a time of an estimation target.

Explanation follows regarding information processing during model training.

At step S100, the CPU 11 groups vehicle data for each vehicle on a day-by-day basis to generate calculation target data. Here, data in which a dimension of data for each trip in the number of trips direction is added to vehicle data stored in a matrix, and is arranged, is generated as the calculation target data. The number of trips direction corresponds to the z-axis direction of FIG. 4A described above, and may be arranged with a number of a trip allocated thereto. The maximum number of trips “a” included in the range of grouping is set as the number of dimensions to be added.

At step S102, the CPU 11 sets the number of calculation target days “b” in the calculation target data.

At step S104, the CPU 11 normalizes (or standardizes) the calculation target data for each item using the following equation (1).

$$= \frac{{x}_{i} - {μ}_{B}}{{σ}_{B}} \qquad ( 1 )$$

In Equation 1, x is the value of the item, μ is the average value, and σ is the standard deviation. It should be noted that, as an example, normalization is performed for each item using the entirety of the target date B, which is a sum of the number of calculation target days “b”. For each item, X is a matrix that summarizes x for the item by the maximum number of trips “a” and the number of calculation target days “b”. X is an example of a first matrix of the present disclosure.

At step S106, the CPU 11 substitutes zero for an item with a standard deviation of zero for the calculation target data.

At step S108, the CPU 11 substitutes zeros into blank portions for the calculation target data.

At step S110, the CPU 11 sets, for the calculation target data, the matrix a×b, the eigenfunction matrix A (a×a), and the eigenvalue 2.

At step S112, the CPU 11 searches for an eigenfunction matrix A that is the smallest by the following equation (2).

$$min \{ \{ d = {‖ {A}^{T} AX - X ‖}^{2} \} \qquad ( 2 )$$

At step S114, the CPU 11 performs principal component analysis to extract a matrix of the principal component (PC (n×a)) from the searched eigenfunction matrix A (a×a) and the dimension n of the principal component serving as the extraction target. It should be noted that in order to determine the n of the n-dimension, the contribution rate for each principal component is obtained using the eigenvalue λ, and n is calculated by cumulative summing up to a predetermined contribution rate. PC is an example of a second matrix in the present disclosure.

At step S116, the CPU 11 generates training data in which the vehicle data for b days is aligned in n dimensions, by calculation of the matrix X and the extracted matrix PC of the principal component. The training data (S) implements S=PC·X and is obtained from a matrix of n×b. X is a matrix of items of calculation target data. The matrix X is described below.

At step S118, the CPU 11 uses the generated training data to train a model of the neural network, and stores the trained model in the storage section 112.

Explanation follows regarding information processing during estimation.

At step S200, the CPU 11 acquires the vehicle data to be estimated, and shapes the trained model into the same number of dimensions as the number of dimensions of the trained training data. By shaping the number of dimensions corresponding to the input of the trained model, a case in which the number of trips is different or a case in which data acquisition is lost for each item can be dealt with.

At step S202, the CPU 11 inputs the shaped vehicle data to the trained model, and outputs an estimation result of the trained model. The trained model calculates a weighting matrix of the network according to the label data, and outputs an estimation result.

Specific examples of training data that is generated are described below.

As an example, explanation follows regarding a case in which eight trips per day is the maximum number of trips “a” and the number of calculation target days “b” is five days in the range selected in the grouping.

The vehicle data for each trip is indicated by the value of the matrix X {x₁₁, x₁₂ . . . xᵢⱼ}. In this regard, i is treated as the number corresponding to a trip, and j is treated as the number corresponding to each day. A case in which X is reduced to two dimensions, namely n=2, is assumed. Further, the matrix X includes a blank portion due to a day on which there is no value for an item, or a value cannot be acquired, since the maximum number of trips is extended to “a”. The average value or zero is substituted into a blank portion of the matrix X to fill in the value.

The matrix X of items of calculation target data for each trip, which is original, is data of an 8×5 matrix of X₁₁ to X₈₅, as illustrated in the following equation (3).

$${\overbrace{( \begin{matrix}{x}_{11} & {x}_{12} & {x}_{13} & {x}_{14} & {x}_{15} \\ {x}_{21} & {x}_{22} & {x}_{23} & {x}_{24} & {x}_{25} \\ {x}_{31} & {x}_{32} & {x}_{33} & {x}_{34} & {x}_{35} \\ {x}_{41} & {x}_{42} & {x}_{43} & {x}_{44} & {x}_{45} \\ {x}_{51} & {x}_{52} & {x}_{53} & {x}_{54} & {x}_{55} \\ {x}_{61} & {x}_{62} & {x}_{63} & {x}_{64} & {x}_{65} \\ {x}_{71} & {x}_{72} & {x}_{73} & {x}_{74} & {x}_{75} \\ {x}_{81} & {x}_{82} & {x}_{83} & {x}_{84} & {x}_{85}\end{matrix} )}}^{X ( 8 \times 5 )} \qquad ( 3 )$$

Next, the matrix PC of the following equation (4) that acquired PC1 and PC2 is generated. The number of elements in the matrix PC is determined according to the dimension n to be compressed.

$${\overbrace{PC = ( \begin{matrix}{A}_{11} & {A}_{12} & {A}_{13} & {A}_{14} & {A}_{15} & {A}_{16} & {A}_{17} & {A}_{18} \\ {A}_{21} & {A}_{22} & {A}_{23} & {A}_{24} & {A}_{25} & {A}_{26} & {A}_{27} & {A}_{28}\end{matrix} )}}^{PC ( 2 \times 8 )} \begin{matrix}← PC 1 \\ ← PC 2\end{matrix} \qquad ( 4 )$$

As the training data S, five days worth of data reduced to two dimensions is obtained, as illustrated in the following equation (5). This means that the eight trips of vehicle data has been compressed to two dimensions.

$$S = PC \cdot X = ( \begin{matrix}{S}_{11} & {S}_{12} & {S}_{13} & {S}_{14} & {S}_{15} \\ {S}_{21} & {S}_{22} & {S}_{23} & {S}_{24} & {S}_{25}\end{matrix} ) \qquad ( 5 )$$

It should be noted that in a case in which n=1, the training data S may be compressed to one dimension using only the PC1 as a one-dimensional matrix.

As described above, the information processing device 110 of the present exemplary embodiment can train a model of a neural network with the number of dimensions of data aligned.

It should be noted that in the above-described exemplary embodiment, any of various types of processors other than the CPU 11 may execute the processing that the CPU 11 executes by reading software (a program). Examples of such processors include a Programmable Logic Device (PLD) in which the circuit configuration can be modified post-manufacture, such as a Field-Programmable Gate Array (FPGA), a graphics processing unit (GPU) or a specialized electric circuit that is a processor with a specifically-designed circuit configuration for executing specific processing, such as an Application Specific Integrated Circuit (ASIC). Further, each of the above-described processing may be executed by one of these various types of processors, or may be executed by combining two or more of the same type or different types of processors (for example, plural FPGAs, or a combination of a CPU and an FPGA, or the like). Moreover, a hardware configuration of the various processors is specifically formed as an electric circuit combining circuit elements such as semiconductor elements.

Moreover, explanation has been given regarding an aspect in which the information processing program is stored (installed) in advance on a non-transitory storage medium that is readable by a computer in the above-described exemplary embodiment. For example, the information processing program is stored in advance in the ROM 12 or the storage 14. However, there is no limitation thereto, and the respective programs may be provided in a format recorded on a non-transitory storage medium such as a compact disc read only memory (CD-ROM), a digital versatile disc read only memory (DVD-ROM), or universal serial bus (USB) memory. Alternatively, the information processing program may be provided in a format downloadable from an external device via a network.

The flow of processing described in the above-described exemplary embodiment is an example, and unnecessary steps may be deleted, new steps may be added, or the processing order may be rearranged within a range not departing from the spirit of the present disclosure.

What is claimed is:

1. An information processing method comprising, by a computer:
receiving vehicle data, which is data relating to a vehicle and is accumulated for each predetermined period of time and for each unit relating to a predetermined operation, a number of units in the data relating to the predetermined operation being different for each predetermined period of time in accordance with use by a user:
generating, by using principal components obtained by principal component analysis of the vehicle data, training data by reducing the number of units relating to the predetermined operation in the vehicle data, and aligning a number of dimensions of the vehicle data; and
training a model of a neural network by using the training data.

2. The information processing method according to claim 1, further comprising:
grouping the vehicle data on a day-by-day basis as the predetermined period of time, and setting a maximum number of the units relating to the predetermined operation and a number of calculation target days, among the vehicle data that has been grouped;
creating, for each item of the vehicle data, a first matrix according to the maximum number and the number of calculation target days;
creating a second matrix according to the principal component obtained by the principal component analysis; and
generating the training data by calculation of the first matrix and the second matrix.

3. The information processing method according to claim 2, wherein an average value or zero is substituted into a blank portion of the first matrix to fill in a value.

4. The information processing method according to claim 1, further comprising:
shaping a dimension of the vehicle data into a number of dimensions of the training data that was used in training of the trained model, by using a trained model that was training using the training data; and
outputting an estimation result of the trained model.

5. An information processing device, comprising:
a memory; and
a processor coupled to the memory, the processor being configured to:
receive vehicle data, which is data relating to a vehicle and is accumulated for each predetermined period of time and for each unit relating to a predetermined operation, a number of units in the data relating to the predetermined operation being different for each predetermined period of time in accordance with use by a user:
generate, by using principal components obtained by principal component analysis of the vehicle data, training data by reducing the number of units relating to the predetermined operation in the vehicle data, and aligning a number of dimensions of the vehicle data; and
train a model of a neural network by using the training data.

6. The information processing device according to claim 5, wherein the processor is configured to:
group the vehicle data on a day-by-day basis as the predetermined period of time, and set a maximum number of the units relating to the predetermined operation and a number of calculation target days, among the vehicle data that has been grouped;
create, for each item of the vehicle data, a first matrix according to the maximum number and the number of calculation target days;
create a second matrix according to the principal component obtained by the principal component analysis; and
generate the training data by calculation of the first matrix and the second matrix.

7. The information processing device according to claim 6, wherein an average value or zero is substituted into a blank portion of the first matrix to fill in a value.

8. The information processing device according to claim 5, wherein the processor is configured to:
shape a dimension of the vehicle data into a number of dimensions of the training data that was used in training of the trained model, by using a trained model that was trained using the training data; and
output an estimation result of the trained model.

9. A non-transitory computer readable medium storing a program executable by a computer to perform a process for information processing, the process comprising:
receiving vehicle data, which is data relating to a vehicle and is accumulated for each predetermined period of time and for each unit relating to a predetermined operation, a number of units in the data relating to the predetermined operation being different for each predetermined period of time in accordance with use by a user:
generating, by using principal components obtained by principal component analysis of the vehicle data, training data by reducing the number of units relating to the predetermined operation in the vehicle data, and aligning a number of dimensions of the vehicle data; and
training a model of a neural network by using the training data.

10. The non-transitory computer readable medium according to claim 9, further comprising:
grouping the vehicle data on a day-by-day basis as the predetermined period of time, and setting a maximum number of the units relating to the predetermined operation and a number of calculation target days, among the vehicle data that has been grouped;
creating, for each item of the vehicle data, a first matrix according to the maximum number and the number of calculation target days;
creating a second matrix according to the principal component obtained by the principal component analysis; and
generating the training data by calculation of the first matrix and the second matrix.

11. The non-transitory computer readable medium according to claim 10, wherein an average value or zero is substituted into a blank portion of the first matrix to fill in a value.

12. The non-transitory computer readable medium according to claim 9, further comprising:
shaping a dimension of the vehicle data into a number of dimensions of the training data that was used in training of the trained model, by using a trained model that was trained using the training data; and
outputting an estimation result of the trained model.
